(19) United States
(12) Patent Application Publication
(10) Pub. No.: US 2014/0230888 A1
(43) Pub. Date: Aug. 21, 2014

(54) SOLAR CELL AND METHOD OF MANUFACTURING THE SAME

(71) Applicant: Samsung SDI CO., LTD., Yongin-si (KR)

(72) Inventors: Jeong-Hoon Kim, Yongin-si (KR); Sang-Hyuck Ahn, Yongin-si (KR); Hyun-Chul Kim, Yongin-si (KR); Si-Young Cha, Yongin-si (KR); Nam-Seok Baik, Yongin-si (KR)

(73) Assignee: SAMSUNG SDI CO., LTD., Yongin-si (KR)

(21) Appl. No.: 14/058,161

(22) Filed: Oct. 18, 2013

Related U.S. Application Data
(60) Provisional application No. 61/766,585, filed on Feb. 19, 2013.

(51) Int. Cl. H01L 31/0296; H01L 31/18

(52) U.S. Cl. CPC H01L 31/0296; H01L 31/1828
USPC 136/255; 438/93

(57) ABSTRACT

A solar cell including a light absorption layer including a p-type compound semiconductor; and a buffer layer including a first buffer layer and a second buffer layer on the light absorption layer, the second buffer layer being between the first buffer layer and light absorption layer, and a zinc sulfide (ZnS) concentration of the first buffer layer being greater than a ZnS concentration of the second buffer layer is disclosed. Methods of manufacturing the solar cell are also disclosed.

### CROSS-REFERENCE TO RELATED APPLICATION

This application claims priority to and the benefit of U.S. Provisional Application No. 61/766,585, filed on Feb. 19, 2013 in the U.S. Patent and Trademark Office, the entire content of which is incorporated herein by reference.

### BACKGROUND

1. Field

Embodiments of the present invention relate to a solar cell and a method of manufacturing the same.

2. Related Art

Solar cells are an alternative energy source that converts solar energy into electric energy, produces less pollutants (as compared to fossil fuels), and is semi-permanent.

Silicon solar cells may include bulky mono-crystalline silicon or polycrystalline silicon, or amorphous silicon. Silicon solar cells may have high efficiency, but their manufacturing costs are high. Organic solar cells may have low manufacturing costs, but their efficiency and stability are low. Compound semiconductor solar cells have lower manufacturing costs and higher efficiency and stability than silicon solar cells.

A compound semiconductor solar cell may include a light absorption layer formed of a p-type compound semiconductor and an n-type buffer layer disposed on the p-type compound semiconductor. The light absorption layer may be a CIGS thin film, such as Cu(In, Ga)Se₂, and the buffer layer may be formed of, for example, CdS, ZnO, or ZnS.

However, the efficiency of solar cells including such buffer layers may be further improved.

Accordingly, a buffer layer that further improves efficiency of a solar cell is desirable.

### SUMMARY

An aspect of an embodiment according to the present invention is directed toward a solar cell including a buffer layer having a novel structure.

Another aspect of an embodiment according to the present invention is directed toward a method of manufacturing the solar cell.

According to an embodiment of the present invention, a solar cell includes: a light absorption layer including a p-type compound semiconductor; and a buffer layer including a first buffer layer and a second buffer layer on the light absorption layer, the second buffer layer being between the first buffer layer and the light absorption layer, and a zinc sulfide (ZnS) concentration of the first buffer layer being greater than a ZnS concentration of the second buffer layer.

The solar cell may further include a window layer on the buffer layer, the window layer including an n-type metal oxide semiconductor.

In some embodiments, the buffer layer has a ZnS concentration gradient and a ZnS concentration of the buffer layer decreases along a direction from the first buffer layer to the second buffer layer.

The ZnS concentration of the buffer layer may continuously decrease along the direction from the first buffer layer to the second buffer layer.

In some embodiments, a ratio of ZnS to Zn(S,O,OH) in the first buffer layer is in a range of about 0.25 to about 0.63.

In some embodiments, a ratio of ZnS to Zn(S,O,OH) in the second buffer layer may be less than about 0.25.

A thickness ratio of a thickness of the first buffer layer to a thickness of the second buffer layer is in a range of 3:1 to 1:3.

A thickness of the first buffer layer may substantially identical to a thickness of the second buffer layer.

The buffer layer may have a thickness in a range of about 1 nm to about 2 μm.

In some embodiments, the p-type compound semiconductor of the light absorption layer is represented by Composition Formula 1: CuIn₁₋ₓGa(S_{y}Se_{1-y})₂, wherein 0≦x<1, and 0<y<1.

The first buffer layer may have a thickness in a range of about 0.5 nm to about 1 μm.

In some embodiments, a surface of the light absorption layer has a sulfur (S) concentration of 0.5 atom % or more.

According to an embodiment of the present invention, a solar cell includes: a light absorption layer including a p-type compound semiconductor; and a buffer layer on the light absorption layer, the buffer layer having a ZnS concentration gradient, and a ZnS concentration of the buffer layer increasing along a direction from a surface of the buffer layer facing the light absorption layer to a surface of the buffer layer away from the light absorption layer.

According to another embodiment of the present invention, a method of manufacturing a solar cell includes: preparing an aqueous solution including zinc sulfate (ZnSO₄), thiourea (SC(NH₂)₂), and ammonium hydroxide (NH₄OH); and immersing a light absorption layer including the p-type compound semiconductor in the aqueous solution for 7 minutes or more to form a buffer layer on the light absorption layer.

In some embodiments, the immersing includes immersing the light absorption layer in the aqueous solution for a time period in a range of 7 minutes to 30 minutes.

The temperature of the aqueous solution may be in a range of about 55° C. to about 70° C.

In some embodiments, a concentration of zinc sulfate in the aqueous solution is in a range of about 0.01 M to about 0.1 M.

A concentration of the thiourea in the aqueous solution may be in a range of about 0.2 M to about 1.3 M.

In some embodiments, a concentration of the ammonium hydroxide in the aqueous solution is in a range of about 1 M to about 5 M.

A pH of the aqueous solution may be in a range of about 10 to about 13.

In some embodiments, the method further includes annealing the buffer layer at a temperature in a range of about 100° C. to about 300° C.

According to aspects of embodiments according to the present invention, due to the inclusion of a buffer layer having a novel structure, open voltage and conversion efficiency of a solar cell may be improved.

### BRIEF DESCRIPTION OF THE DRAWINGS

The accompanying drawings, together with the specification, illustrate embodiments of the present invention, and, together with the description, serve to explain the principles of the present invention.

FIG. 1 is a schematic diagram of a thin film solar cell according to an embodiment of the present invention.

FIGS. 2A-2C show Auger electron spectroscopy (AES) spectra of solar cells prepared according to Preparation Examples 1 to 2 and Comparative Preparation Example 1.

FIG. 3 shows a graph showing surface analysis results and conversion efficiency of solar cells prepared according to Examples 1 to 5, Reference Example 1 and Comparative Example 1.

### DETAILED DESCRIPTION

In the following detailed description, only certain exemplary embodiments of the present invention are shown and described, by way of illustration. As those skilled in the art would recognize, the invention may be embodied in many different forms and should not be construed as being limited to the embodiments set forth herein. Also, in the context of the present application, when a first element is referred to as being “on” a second element, it can be directly on the second element or be indirectly on the second element with one or more intervening elements interposed therebetween. Like reference numerals designate like elements throughout the specification.

Hereinafter, solar cells and methods of manufacturing the same, according to embodiments of the present invention, are described in further detail.

A solar cell according to an embodiment of the present invention includes a light absorption layer including a p-type compound semiconductor, a buffer layer that is disposed on the light absorption layer and contains ZnS, and a window layer that is disposed on the buffer layer and includes an n-type metal oxide semiconductor, wherein the buffer layer includes a second buffer layer disposed on the light absorption layer and a first buffer layer disposed on the second buffer layer, and a ZnS content (e.g., concentration) of the first buffer layer is greater than a ZnS content (e.g., concentration) of the second buffer layer.

Since, according to embodiments of the present invention, the first buffer layer has greater ZnS content (e.g., concentration) than the second buffer layer, open voltage and conversion efficiency of the solar cell may be improved. For example, since the first buffer layer has greater ZnS content than the second buffer layer, a bandgap is high. Accordingly, efficiency of the solar cell may be improved by controlling a thickness of the first buffer layer in order to align the bandgaps of the buffer layer and the light absorption layer.

In one embodiment, the ZnS content of the buffer layer of the solar cell has a concentration gradient in which the ZnS content (e.g., concentration) decreases in a direction (e.g., along a direction) from the first buffer layer to the second buffer layer. For example, the ZnS content of the buffer layer may continuously decrease in the direction from the first buffer layer to the second buffer layer. As used herein, the term “concentration gradient” has a meaning generally accepted in the art, e.g., a gradient in concentration of a material, for example ZnS, as a function of a distance through (or along) the buffer layer. In some embodiments, the concentration of the material is higher at the first buffer layer and decreases towards the second buffer layer. In some embodiments, when a content (or concentration) of the material continuously decreases, there is a continuous decrease in the content of the material, for example ZnS, at the level of accuracy at which this parameter is measured, for example, the level of accuracy provided by Auger electron spectroscopy (AES).

For example, a ratio of ZnS content to Zn(S,O,OH) content, ZnS/Zn(S,O,OH), which is calculated from the Auger electron spectroscopy (AES) spectrum of the first buffer layer, may be in a range of about 0.25 to about 0.63. For example, a ratio of ZnS content to Zn(S,O,OH) content, which is calculated from the Auger electron spectroscopy (AES) spectrum of the first buffer layer, may be in a range of about 0.30 to about 0.60. When the ratio of ZnS/Zn(S,O,OH) in the first buffer layer is less than 0.25 or greater than 0.36, conversion efficiency of the solar cell may decrease.

For example, a ratio of ZnS content to Zn(S,O,OH) content, which is calculated from the Auger electron spectroscopy (AES) spectrum of the second buffer layer, may be less than 0.25. When the ratio of ZnS/Zn(S,O,OH) in the second buffer layer is 0.25 or more, conversion efficiency of the solar cell may decrease.

For example, a thickness ratio of the first buffer layer to the second buffer layer in the solar cell may be in a range of 3:1 to 1:3. For example, a thickness ratio of the first buffer layer to the second buffer layer in the solar cell may be in a range of 1.1:0.9 to 0.9:1.1. For example, the first buffer layer to the second buffer layer in the solar cell may have a substantially identical thickness. When the first buffer layer and the second buffer layer have such thickness ratios, conversion efficiency of the solar cell may improve.

The first buffer layer and the second buffer layer of the solar cell may be monolithic. For example, the first buffer layer and the second buffer layer may be continuously formed without a distinguishable interface therebetween (e.g., as a single buffer layer). For example, regarding a single buffer layer prepared by using one preparation method, based on a thickness direction of the buffer layer, an upper half thereof may be referred to as a first buffer layer and a lower half thereof may be referred to as a second buffer layer. In addition, throughout the first buffer layer and the second buffer layer, the ZnS content (e.g., concentration) may continuously decrease in the direction from the first buffer layer to the second buffer layer.

The buffer layer of the solar cell may have a thickness in a range of about 1 nm to about 2 μm. For example, a thickness of the buffer layer (e.g., a combined thickness of the first buffer layer and the second buffer layer) may be in a range of about 1 nm to about 200 nm, but it is not limited thereto. The thickness of the buffer layer may suitably vary within the scope of the present invention.

A thickness of the first buffer layer of the buffer layer may be in a range of about 0.5 nm to about 1 μm. For example, a thickness of the first buffer layer may be in a range of about 0.5 nm to about 100 nm. In some embodiments, a thickness of the second buffer layer of the buffer layer may be in a range of about 0.5 nm to about 1 μm. For example, a thickness of the second buffer layer may be in a range of about 0.5 nm to about 100 nm.

The light absorption layer of the solar cell may have a Group I-III-VI2 chalcopyrite structure having p-type conductivity. For example, the light absorption layer may be a thin film including a multinary compound semiconductor, such as CuInSe₂, Cu(In,Ga)Se₂, or Cu(In,Ga)(S,Se)₂.

For example, the light absorption layer of the solar cell may be a thin film having a compound semiconductor having Composition Formula 1 below.

CuIn₁₋ₓGaₓ(S_{y}Se_{1-y})₂ Composition Formula 1

wherein 0≦x<1, 0<y<1.

In some embodiments, the light absorption layer may be a selenide-based CIS-based light absorption layer, a sulfide-based CIS-based light absorption layer, or a selenide.sulfide-based CIS-based light absorption layer. The selenide-based CIS-based light absorption layer may include CuInSe₂, Cu(In,Ga)Se₂, or CuGaSe₂; the sulfide-based CIS-based light absorption layer may include CuInS₂, Cu(InGa)S₂, or CuGaS₂; and the selenide.sulfide-based CIS-based light absorption layer may include CuIn(S,Se)₂, Cu(In,Ga)(SSe)₂, or CuGa(S,Se)₂. In another embodiment of the present invention, the light absorption layer may further include a surface layer. Examples of such a light absorption layer include CuInSe₂with CuIn(S,Se)₂ as a surface layer; Cu(In,Ga)Se₂ with CuIn(S,Se)₂ as a surface layer; Cu(InGa)(SSe)₂ with CuIn(S,Se)₂ as a surface layer; CuGaSe₂ with Culn(S,Se)₂ as a surface layer; Cu(In,Ga)Se₂ with Cu(In,Ga)(S,Se)₂ as a surface layer; CuGaSe₂ with Cu(In,Ga)(S,Se)₂ as a surface layer; Cu(In,Ga)Se₂ with CuGa(S,Se)₂ as a surface layer; and CuGaSe₂ with CuGa(S,Se)₂ as a surface layer.

The light absorption layer may be formed by, for example, selenization/sulfuration or co-deposition of multiple materials. In some embodiments, when the light absorption layer is formed by selenization/sulfuration, either a stack structure including copper (Cu), indium (In), or gallium (Ga), or a mixed crystal of metal precursor film (Cu/In, Cu/Ga, Cu—Ga alloy/In, Cu—Ga—In alloy, etc.) is formed on a surface of a metal opposite electrode layer by, for example, sputtering or deposition, and then a heat treatment is performed thereon under a selene (e.g., selenium) and/or sulfur-containing atmosphere to form the light absorption layer. In some embodiments, when the light absorption layer is formed by co-deposition of multiple materials, a raw material including copper (Cu), indium (In), gallium (Ga), and selenium (Se) are concurrently or simultaneously deposited (e.g., co-deposited) at an appropriate combination on a glass substrate with an opposite electrode layer thereon which is heated at a temperature of 500° C. or more to form the light absorption layer.

A surface of the light absorption layer of the solar cell (e.g., a portion of the light absorption layer up to 10 nm in depth from the surface of the light absorption layer) may have a sulfur(S) concentration of 0.5 atom % or more. For example, a surface of the light absorption layer may have a sulfur(S) concentration of 3 atom % or more. When the surface of the light absorption layer has a sulfur concentration of 0.5 atom % or more, an optical bandgap at an optical incident surface at the solar cell may increase and thus, incident light may be more effectively absorbed. In addition, the interfacial characteristics of the light absorption layer and the buffer layer may also be improved.

A thickness of the light absorption layer may be in a range of about 1 μm to about 3 μm. For example, the light absorption layer may have a thickness in a range of about 1.5 μm to about 2 μm, but the thickness thereof is not limited thereto, and may vary within the scope of the present invention.

In some embodiments, the window layer of the solar cell is a film that has n-type conductivity, a wide bandgap, transparency, and low resistance. An example thereof is a zinc oxide-based thin film or an indium tin oxide (ITO) thin film. An n-type window layer, in the case of a zinc-oxide thin film, may include, as a dopant, a Group III element, for example, aluminum (Al), gallium (Ga), boron (B), or a combination thereof. The window layer may be a transparent conductive layer having a thickness in a range of about 5 nm to about 2.5 μm. For example, a thickness of the window layer may be in a range of about 50 nm to about 2 μm, but is not limited thereto, and the thickness of the window layer may vary within the scope of the present invention.

The buffer layer of the solar cell may further include a third buffer layer disposed on the first buffer layer. The third buffer layer may include (e.g., be formed of) an intrinsic ZnO layer. A thickness of the third buffer layer may be in a range of about 10 nm to about 2 μm. For example, a thickness of the third buffer layer may be in a range of about 15 nm to about 200 nm, but is not limited thereto, and the thickness of the third buffer layer may vary within the scope of the present invention.

The light absorption layer of the solar cell may be on (e.g., formed on) a supporting substrate. The supporting substrate may be a glass substrate, a plastic substrate, or a metal substrate. The supporting substrate may be rigid or flexible. For example, the supporting substrate may be a soda lime glass substrate. A thickness of the supporting substrate may be in a range of about 0.1 μm to about 100 μm, but is not limited thereto, and the thickness of the supporting substrate may vary within the scope of the present invention.

In some embodiments, a bottom electrode or an opposite electrode is formed between the supporting substrate and the light absorption layer of the solar cell. The opposite electrode may include (e.g., be formed of) Mo, Cr, W, or a combination thereof. For example, the opposite electrode may include (e.g., be formed of) Mo. A thickness of the opposite electrode may be in a range of about 200 nm to about 1000 nm (but is not limited thereto) and the thickness of the opposite electrode may vary within the scope of the present invention.

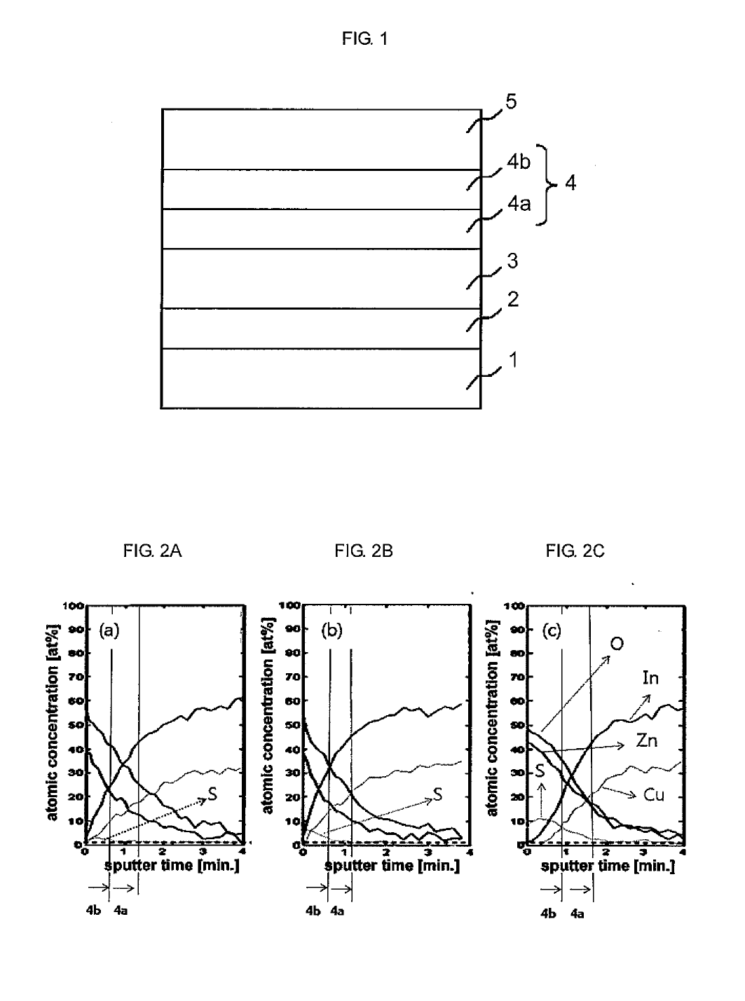

For example, the solar cell may have a structure illustrated in FIG. 1. As illustrated in FIG. 1, a metal opposite electrode layer 2 may be on a glass substrate 1, a light absorption layer 3 may be on the metal opposite electrode layer 2, a buffer layer 4 may be on the light absorption layer 3, and a window layer 5 may be on the buffer layer 4. In some embodiments, the window layer 5 is also a transparent conductive electrode layer. The buffer layer 4 may include a second buffer layer 4a on the light absorption layer and a first buffer layer 4b on the second buffer layer 4a. Although not illustrated in FIG. 1, a third buffer layer may be additionally located between the first buffer layer 4b and the window layer 5.

The buffer layer of the solar cell may be formed by growing a compound semiconductor film from an aqueous solution to form a hetero junction with the light absorption layer by, for example, chemical bath deposition (CBD).

According to another embodiment of the present invention, a method of manufacturing a solar cell includes: preparing an aqueous solution including zinc sulfate (ZnSO₄), thiourea (SC(NH₂)₂) and ammonium hydroxide (NH₄OH) (or, in certain embodiments, a thiourea alternative compound and/or an ammonium hydroxide alternative compound may be used); and immersing a light absorption layer including a p-type compound semiconductor in the aqueous solution for 7 minutes or more (e.g., 15 minutes or more) to form a buffer layer on the light absorption layer. A solar cell manufactured by using the method according to an embodiment of the present invention has high open voltage and conversion efficiency.

Due to the 7 or minutes of immersion of the light absorption layer in the aqueous solution, the first buffer layer may have a higher ZnS content (e.g., concentration) than the second buffer layer. When the immersion time of the light absorption layer in the aqueous solution is less than 7 minutes, a difference in the ZnS content (e.g., concentration) of the first buffer layer and the second buffer layer is negligible and thus, conversion efficiency of the solar cell may decrease.

For example, the light absorption layer may be immersed in the aqueous solution for a time period in a range of about 7 minutes to about 30 minutes. For example, the light absorption layer may be immersed in the aqueous solution for a time period in a range of about 15 minutes to about 30 minutes. When the immersion time is too long, the first buffer layer may be too thick such that a series resistance of the buffer layer increases and thus conversion efficiency of the solar cell may decrease.

A temperature of the aqueous solution may be in a range of about 55° C. to about 70° C., while the light absorption layer is being immersed in the aqueous solution. For example, a temperature of the aqueous solution may be in a range of about 57° C. to about 69° C., while the light absorption layer is being immersed in the aqueous solution. For example, a temperature of the aqueous solution may be in a range of about 60° C. to about 68° C., while the light absorption layer is being immersed in the aqueous solution. Within the temperature ranges described above, a solar cell providing high open voltage and conversion efficiency may be obtained. When the temperature of the aqueous solution is lower than 55° C., a reaction rate may decrease, and when the temperature of the aqueous solution is higher than 70° C., the Zn(OH) content (e.g., concentration) of the aqueous solution may be too high.

In the method according to an embodiment of the present invention, the concentration of zinc sulfate in the aqueous solution is in a range of about 0.01 M to about 0.1M. For example, the concentration of the zinc component, for example zinc sulfate, may be in a range of about 0.02M to about 0.05M. For example, the concentration of the zinc component, for example zinc sulfate, may be in a range of, optionally, about 0.03M to about 0.04M. Within the foregoing zinc sulfate concentration range, a buffer layer providing high open voltage and conversion efficiency may be manufactured. When the zinc sulfate concentration in the aqueous solution is less than 0.01M, a reaction rate may decrease, and when the zinc sulfate concentration in the aqueous solution is higher than 0.1M, an increase in a reaction rate may be negligible although manufacturing costs may increase.

In the method according to an embodiment of the present invention, a thiourea concentration in the aqueous solution is in a range of about 0.2M to about 1.3M. For example, a concentration of a thiourea, or an alternative compound thereto, may be in a range of about 0.30M to about 1.0M. For example, a concentration of the thiourea, or the alternative compound thereto, may optionally be in a range of about 0.40M to about 0.70M. Within the foregoing thiourea concentration range described above, a solar cell having high open voltage and conversion efficiency may be manufactured. When the thiourea concentration in the aqueous solution is less than 0.2M, a reaction rate may decrease, and when the thiourea concentration in the aqueous solution is higher than 1.3M, an increase in a reaction rate may be negligible although manufacturing costs may increase.

In the method according to an embodiment of the present invention, an ammonium hydroxide concentration in the aqueous solution is in a range of about 1M to about 5M. For example, a concentration of an ammonium hydroxide, or an alternative compound thereto, may be in a range of about 1.5M to about 4M. For example, the concentration of an ammonium hydroxide, or an alternative compound thereto, may be about 2M to about 3M. Within the foregoing ammonium hydroxide concentration, a solar cell having high open voltage and conversion efficiency may be manufactured. When the ammonium hydroxide concentration in the aqueous solution is less than 1M, efficiency characteristics may decrease, and when the ammonium hydroxide concentration in the aqueous solution is higher than 5M, efficiency characteristics may decrease. In an embodiment of the invention, the above three components (ZnS, thiourea or alternative, and ammonium hydroxide or an alternative) are present in concentrations of about 0.02M to about 0.05M, about 0.30M to about 1.0M and about 1.5M to about 4M, respectively. In an embodiment of the invention, a mole ratio of zinc sulfate : thiourea : ammonium hydroxide may be 1:7˜30:30˜120 in the aqueous solution.

In the method according to an embodiment of the present invention, a pH of the aqueous solution is in a range of about 10 to about 13. For example, a pH of the aqueous solution in the method may be in a range of about 10 to about 12. Within the foregoing pH range of the aqueous solution, a solar cell having high open voltage and conversion efficiency may be manufactured. When a pH of the aqueous solution is less than 10, a reaction rate may decrease, and even when a pH of the aqueous solution is higher than 13, a reaction rate may decrease.

The method according to an embodiment of the present invention further includes, after the forming of the buffer layer, annealing of the buffer layer at a temperature in a range of about 100 to about 300° C., under atmospheric conditions. Due to the annealing, a dense and homogeneous buffer layer may be formed.

In the method according to an embodiment of the present invention, the light absorption layer is located on (e.g., formed on) an insulating substrate (e.g., an electrically insulating substrate) coated with a metal opposite electrode. The metal opposite electrode may be formed by, for example, sputtering.

In the method according to an embodiment of the present invention, the third buffer layer is additionally located on (e.g., formed on) the buffer layer including the first buffer layer and the second buffer layer. The third buffer layer may be formed by, for example, sputtering. The third buffer layer may be formed of intrinsic ZnO.

The window layer may be located on (e.g., formed on) the third buffer layer. The window layer may be a transparent conductive layer. For example, the window layer may be a transparent conductive electrode layer. The window layer may be formed by, for example, sputtering, and may be formed of Al-doped ZnO. In addition, a grid electrode may be additionally located on (e.g., formed on) the window layer by, for example, sputtering. The grid electrode may be formed of Al or the like. A thickness of the grid electrode is not particularly limited, and may be in a range of about 0.1 μm to about 3 μm.

Embodiments of the present invention will now be described in more detail with reference to examples and comparative examples. However, the examples are presented herein for illustrative purpose only, and do not limit the scope of the present invention.

### (Formation of Buffer Layer)

### PREPARATION EXAMPLE 1

An Mo bottom electrode having a thickness of 0.8 μm was formed on a soda lime glass (SLG) substrate with a size of 30 mm×30 mm by sputtering. A Cu(In_{0.7}Ga_{0.3})Se₂ light absorption layer was formed on the Mo bottom electrode by multinary simultaneous deposition.

0.038M zinc sulfate, 0.55M thiourea, and 2.5M ammonium hydroxide were added to distilled water to prepare an aqueous solution having a pH of 10.5 and a temperature of 65° C.

The substrate with the light absorption layer was vertically immersed in the aqueous solution for 15 minutes, and then, dried at room temperature to form a buffer layer. A thickness of the buffer layer was 3 nm. The buffer layer was annealed at a temperature of 200° C. for 1 hour.

### PREPARATION EXAMPLE 2

A solar cell was manufactured in the same manner as in Preparation Example 1, except that the immersion time was 30 minutes.

### COMPARATIVE PREPARATION EXAMPLE 2

A solar cell was manufactured in the same manner as in Preparation Example 1, except that the immersion time was 10 minutes.

### (Manufacturing of Solar Cell)

### EXAMPLE 1

An Mo bottom electrode having a thickness of 0.8 μm was formed on a soda lime glass (SLG) substrate with a size of 30 mm×30 mm by sputtering. A Cu(In_{0.7}Ga_{0.3})(S,Se)₂ light absorption layer was formed on the Mo bottom electrode by co-deposition of multiple materials. A sulfur (S) content of the surface of the light absorption layer was about 20 atom %.

0.038M zinc sulfate, 0.55M thiourea, and 2.5M ammonium hydroxide were added to distilled water to prepare an aqueous solution having a pH of 10.5 and a temperature of 65° C.

The substrate with the light absorption layer was vertically immersed in the aqueous solution for 30 minutes, and then taken out to be dried at room temperature to form a buffer layer. A thickness of the buffer layer was 5 nm. The buffer layer was annealed under atmospheric conditions at a temperature of 200° C. for 1 hour.

Subsequently, an intrinsic ZnO (i-ZnO) third buffer layer having a thickness of 50 nm and an Al-doped ZnO(AZO) window layer having a thickness of 300 nm were sequentially formed on the buffer layer by sputtering, thereby completing the manufacturing of a solar cell.

In the solar cell of this example, an upper half of the buffer layer was a first buffer layer and a lower half of the buffer layer was a second buffer layer. Accordingly, in this example, a thickness ratio of the first buffer layer to the second buffer layer is 1:1.

### EXAMPLE 2

A solar cell was manufactured in the same manner as in Example 1, except that the immersion time was 15 minutes. A thickness of the buffer layer was 3 nm.

### EXAMPLE 3

A solar cell was manufactured in the same manner as in Example 1, except that the immersion time was 12 minutes. A thickness of the buffer layer was 2.5 nm.

### EXAMPLE 4

A solar cell was manufactured in the same manner as in Example 1, except that the immersion time was 10 minutes. A thickness of the buffer layer was 2.3 nm.

### EXAMPLE 5

A solar cell was manufactured in the same manner as in Example 1, except that the immersion time was 7 minutes. A thickness of the buffer layer was 2 nm.

### REFERENCE EXAMPLE 1

A solar cell was manufactured in the same manner as in Example 1, except that the immersion time was 60 minutes.

### COMPARATIVE EXAMPLE 1

A solar cell was manufactured in the same manner as in Example 1, except that the immersion time was 5 minutes.

### EVALUATION EXAMPLE 1

### Surface Composition of CIGSe Substrate

Surface compositions of the substrates on which the buffer layers were formed according to Preparation Examples 1 to 2 and Comparative Preparation Example 1 were analyzed by Auger electron spectroscopy (AES).

FIG. 2 illustrates an AES spectrum.

FIG. 2A shows analysis results of the substrate having a buffer layer thereon prepared according to Comparative Preparation Example 1, FIG. 2B shows analysis results of the substrate having a buffer layer thereon prepared according to Preparation Example 1, and FIG. 2C shows analysis results of the substrate having a buffer layer thereon prepared according to Preparation Example 2. Regarding the buffer layer formed on the light absorption layer, an upper half of the buffer layer was regarded as a first buffer layer (4b) and a lower half of the buffer layer was regarded as a second buffer layer (4a).

Referring to FIGS. 2B and 2C, the first buffer layer (4b) has a higher sulfur (8) content than the second buffer layer (4a), and thus, the sulfur content continuously decreases along a direction from the first buffer layer to the second buffer layer.

Referring to FIG. 2A, the sulfur content of the first buffer layer was similar to the sulfur content of the second buffer layer.

Accordingly, it was confirmed that the first buffer layer adjacent to the window layer has a greater (e.g., higher) ZnS content (e.g., concentration) than the second buffer layer adjacent to the light absorption layer according to embodiments of the present invention.

### EVALUATION EXAMPLE 2

### Surface Composition of CIGSSe Substrate

In the same manner as in Evaluation Example 1, surface compositions of substrates (each substrate including a buffer layer formed thereon) according to Examples 1 to 5, Reference Example 1, and Comparative Example 1, were analyzed by Auger electron spectroscopy (AES).

Regarding the buffer layer formed on the light absorption layer, an upper half of the buffer layer was regarded as a first buffer layer (4b) and a lower half of the buffer layer was regarded as a second buffer layer (4a).

From surface composition analysis results, a ZnS content (e.g., concentration), Zn(S,O,OH) content (e.g., concentration) and a ratio of ZnS to Zn(S,O,OH) included in the first buffer layer and the second buffer layer were calculated.

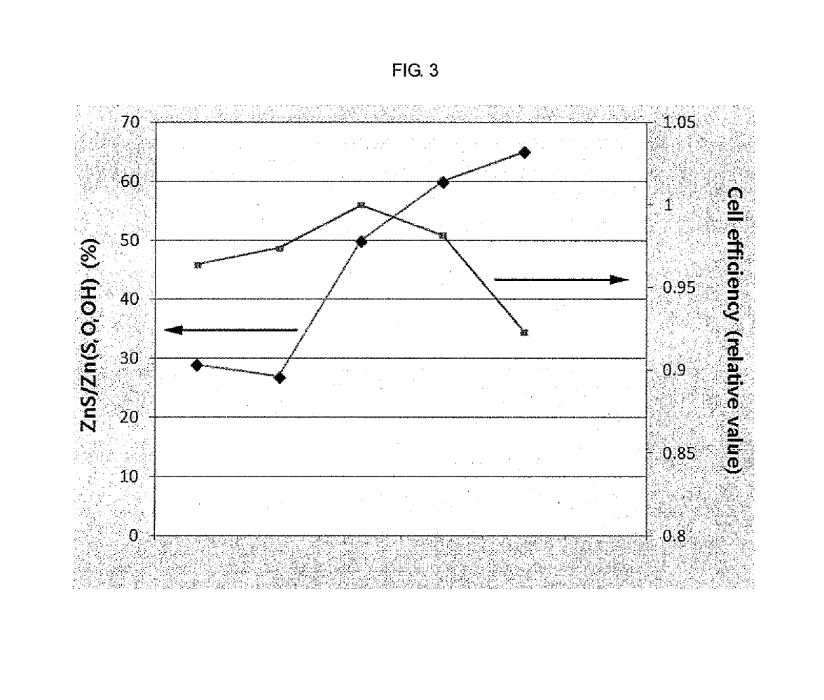

Some calculation results are shown in Table 1 and FIG. 3.

TABLE 1

| | First buffer layer | Second buffer layer |
|---|---|---|
| | ZnS/Zn(S,O,OH) | ZnS/Zn(S,O,OH) |
| | [%] | [%] |
| Example1 | 60 | 25 |
| Example 2 | 50 | 24 |
| Example 3 | 47 | 22 |
| Example 4 | 27 | 20 |
| Example 5 | 29 | 21 |
| Reference | 65 | 27 |
| Example 1 | | |
| Comparative | 18 | 19 |
| Example 1 | | |

As shown in Table 1, regarding Examples 1 to 5, the ZnS/Zn(S,O,OH) content (e.g., concentration) of the first buffer layer was higher than the ZnS/Zn(S,O,OH) content (e.g., concentration) of the second buffer layer. However, regarding Comparative Example 1, the ZnS/Zn(S,O,OH) content (e.g., concentration) of the first buffer layer was lower than the ZnS/Zn(S,O,OH) content (e.g., concentration) of the second buffer layer.

### EVALUATION EXAMPLE 2

### Photoelectric Conversion Efficiency Evaluation

The Current-voltage characteristics of the thin film solar cells manufactured according to Examples 1 to 5, Reference Example 1 and Comparative Example 1 were evaluated under a condition in which light equivalent to 1 sun was irradiated through a filter with air mass (AM) 1.5 and under a dark condition in which light was not irradiated. Herein, “1 sun” refers to an intensity of light source equivalent to one sun, and “AM 1.5” refers to a filter that adjusts a wavelength with solar light.

Optical current voltages of the thin film solar cells manufactured according to Examples 1 to 5, Reference Example 1, and Comparative Example 1 were measured, and then, from a graph of the measured optical current voltages, open voltage, current density, and fill factors were measured, and from the obtained results, efficiency of each solar cell was evaluated. Results thereof are shown in Table 2.

Herein, a Xenon lamp was used as a light source, and a solar condition of the Xenon lamp was corrected by using a reference solar cell (Frunhofer Institute Solare Energiesysteme, Certificate No. C-ISE369, Type of material: Mono-Si+KG filter), and the evaluation was performed at a power density of 100 mW/cm².

Measurement conditions of open voltage, optical current density, energy conversion efficiency, and fill factor are as follows:

(1) Open voltage(V) and optical current density(ffiA/cd): open voltage and optical current density were measured by using Keithley SMU2400; and

(2) Energy conversion efficiency(%) and fill factor (%): energy conversion efficiency was measured by using a solar simulator with 1.5AM 100 mW/cm² (equipped with Xe lamp [300W, Oriel], AM1.5 filter, and Keithley SMU2400), and the fill factor was calculated from conversion efficiency based on the following equation:

$$Fill factor ( \% ) = \frac{{( J \times V )}_{max}}{{J}_{sc} \times {V}_{oc}} \times 100 \qquad Equation$$

wherein J is a value on the Y axis of conversion efficiency curve, V is a value on the X axis of conversion efficiency, and Jsc and Voc are intercept values of the axes, respectively.

Some of the calculation results described above are shown in Table 2 and FIG. 3.

TABLE 2

| | | | | Conversion |
|---|---|---|---|---|
| | | | | efficiency(η) |
| | | | | [%] |
| | Current | Open voltage | Fill factor | (values in |
| | density (J_{sc}) | (V_{oc}) | (FF) | parentheses are |
| | [mA/cm²] | [V] | [%] | relative values) |
| Example 1 | 31.4 | 0.664 | 71.10 | 14.84 (0.98) |
| Example 2 | 31.5 | 0.670 | 71.7 | 15.14 (1.00) |
| Example 3 | 31.7 | 0.657 | 69.90 | 14.57 (0.96) |
| Example 4 | 31.8 | 0.668 | 69.10 | 14.68 (0.97) |
| Example 5 | 31.6 | 0.670 | 68.77 | 14.56 (0.96) |
| Reference | 34 | 0.680 | 48.4 | 11.23 (0.74) |
| Example 1 | | | | |
| Comparative | 31.9 | 0.653 | 69.30 | 14.45 (0.95) |
| Example 1 | | | | |

As shown in Table 2 and FIG. 3, the solar cells of Examples 1 to 5 have improved open voltage and conversion efficiency as compared to the solar cell of Comparative Example 1.

While the present invention has been described in connection with certain embodiments, it is to be understood that the invention is not limited to the disclosed embodiments, but, on the contrary, is intended to cover various modifications and equivalent arrangements included within the spirit and scope of the appended claims, and equivalents thereof.

Explanation of Reference numerals of the Drawings

| | |
|---|---|
| 1: glass substrate | 2: metal opposite electrode layer |
| 3: light absorption layer | 4: buffer layer |
| 4a: second buffer layer | 4b: first buffer layer |
| 5: window layer (transparent electrode) | |

What is claimed is:

1. A solar cell comprising:
a light absorption layer comprising a p-type compound semiconductor; and
a buffer layer comprising a first buffer layer and a second buffer layer on the light absorption layer, the second buffer layer being between the first buffer layer and the light absorption layer, and a zinc sulfide (ZnS) concentration of the first buffer layer being greater than a ZnS concentration of the second buffer layer.

2. The solar cell of claim 1, wherein the buffer layer has a ZnS concentration gradient and a ZnS concentration of the buffer layer decreases along a direction from the first buffer layer to the second buffer layer.

3. The solar cell of claim 2, wherein the ZnS concentration of the buffer layer continuously decreases along the direction from the first buffer layer to the second buffer layer.

4. The solar cell of claim 1, wherein a ratio of ZnS to Zn(S,O,OH) in the first buffer layer is in a range of about 0.25 to about 0.63.

5. The solar cell of claim 1, wherein a ratio of ZnS to Zn(S,O,OH) in the second buffer layer is less than about 0.25.

6. The solar cell of claim 1, wherein a thickness ratio of a thickness of the first buffer layer to a thickness of the second buffer layer is in a range of 3:1 to 1:3.

7. The solar cell of claim 1, wherein a thickness of the first buffer layer is substantially identical to a thickness of the second buffer layer.

8. The solar cell of claim 1, wherein the buffer layer has a thickness in a range of about 1 nm to about 2 μm.

9. The solar cell of claim 1, wherein the p-type compound semiconductor of the light absorption layer is represented by Composition Formula 1:
CuIn₁₋ₓGa(S_{y}Se_{1-y})₂ [Composition Formula 1]
wherein 0≦x<1, and 0<y<1.

10. The solar cell of claim 1, wherein the first buffer layer has a thickness in a range of about 0.5 nm to about 1 μm.

11. The solar cell of claim 1, wherein a surface of the light absorption layer has a sulfur (S) concentration of 0.5 atom % or more.

12. A solar cell comprising:
a light absorption layer comprising a p-type compound semiconductor; and
a buffer layer on the light absorption layer, the buffer layer having a ZnS concentration gradient, and a ZnS concentration of the buffer layer increasing along a direction from a surface of the buffer layer facing the light absorption layer to a surface of the buffer layer away from the light absorption layer.

13. A method of manufacturing a solar cell, the method comprising:
preparing an aqueous solution comprising zinc sulfate (ZnSO₄), thiourea (SC(NH₂)₂), and ammonium hydroxide (NH₄OH); and
immersing a light absorption layer comprising a p-type compound semiconductor in the aqueous solution for 7 minutes or more to form a buffer layer on the light absorption layer.

14. The method of claim 13, wherein the immersing comprises immersing the light absorption layer in the aqueous solution for a time period in a range of 7 minutes to 30 minutes.

15. The method of claim 13, wherein a temperature of the aqueous solution is in a range of about 55° C. to about 70° C.

16. The method of claim 13, wherein a concentration of zinc sulfate in the aqueous solution is in a range of about 0.01 M to about 0.1 M.

17. The method of claim 13, wherein a concentration of the thiourea in the aqueous solution is in a range of about 0.2 M to about 1.3 M.

18. The method of claim 13, wherein a concentration of the ammonium hydroxide in the aqueous solution is in a range of about 1 M to about 5 M.

19. The method of claim 13, wherein a pH of the aqueous solution is in a range of about 10 to about 13.

20. The method of claim 13, wherein the method further comprises annealing the buffer layer at a temperature in a range of about 100° C. to about 300° C.
